(19) United States
(12) Patent Application Publication
(10) Pub. No.: US 2001/0003367 A1
(43) Pub. Date: Jun. 14, 2001

(54) TRENCHED DMOS DEVICE WITH LOW GATE CHARGES

(76) Inventors: FWU-IUAN HSHIEH, SARATOGA, CA (US); KOON CHONG SO, SAN JOSE, CA (US); YAN MAN TSUI, UNION CITY, CA (US)

Correspondence Address: BO-IN LIN, 13445 MANDOLI DRIVE, LOS ALTOS HILLS, CA, 94022

(21) Appl. No.: 09/096,931

(22) Filed: Jun. 12, 1998

(51) Int. Cl. H01L 29/76

(52) U.S. Cl. 257/330

(57) ABSTRACT

This invention discloses a vertical DMOS transistor cell formed in a semiconductor substrate of a first conductivity type with a top surface and a bottom surface. The vertical DMOS transistor cell includes a trenched gate comprising polysilicon filling a trench opened from the top surface disposed substantially in a middle portion of the cell. The DMOS transistor cell further includes a source region of the first conductivity type surrounding the trenched gate near the top surface of the substrate. The DMOS transistor cell further includes a body region of a second conductivity type encompassing the source region. The body region extends vertically toward the bottom surface of the substrate having a depth slightly lower than a bottom of the trenched gate. The body region surrounding the trenched gate and further laterally extends with a small distance under the bottom of the trenched gate to cover all areas adjacent to bottom corners of the trenched gate.

### BACKGROUND OF THE INVENTION

1. Field of the Invention

This invention relates generally to the structure and fabrication process of trenched DMOS power transistors. More particularly, this invention relates to a novel and improved structure and process for fabricating high density trenched DMOS power device with reduce gate charges for achieving higher switching speed and gate oxide integrity.

2. Description of the Prior Art

In developing a technology to further shrink the cell size of a power DMOS transistor, a person of ordinary skill in the art is confronted with a difficulty that there is a limit in attempting to improve the switching speed. This is true particularly when the trenched-gate-configuration is implemented in order to achieve a higher cell density. The difficulty is related to the increase gate to drain overlapping area because of the channel width increased per unit area. As a result of the increased gate-to-drain overlapping areas, higher gate-to-drain capacitance, i.e., Cgd, is generated when larger amount of charges are retained in the greater overlapping areas. This difficulty can be understood by reviewing the cell structures disclosed by a few prior art DMOS power devices.

Bulucea et al. disclose in U.S. Pat. No. 5,072,266, cell structures for the purpose of strengthening the device ruggedness. Referring to FIG. 1A for the cell structure of this trench DMOS transistor according to Bulucea et al. The trench DMOS transistor as shown in FIG. 1A provides the advantages that this device has a good ruggedness because of a deep p+ body, which is made deeper than the trench gate. Bulucea et al. disclose a device structure and fabrication method to achieve a controlled bulk semiconductor breakdown. The object of preventing a trench surface breakdown by controlling a bulk breakdown is achieved by taking advantage of the position of the gate in the trench and by using a two dimensional “field-shaping” doping profile. The doping profile includes a central deep p+ layer that is laterally adjacent to a p body layer and vertically adjacent to an epitaxial layer of appropriate thickness. The device that disclosed by this invention provides an improved device profile to suppress the surface breakdown. The transistor also has good gate oxide integrity at the bottom of the trench gate since the avalanche breakdown is directed to occur below the deep p+ body.

With this transistor cell configuration, there are large interface areas between the trenched gates 40 and the drain. Specifically, the areas at the bottom half of the trenched gates not covered by the P+ body 25 regions are interfaced with the drain 15 by a thin gate-oxide layer acting as an insulator. A gate-to-drain capacitance Cgd is formed with large charge-retention areas leads to a large Cgd capacitance. A large gate-to-drain capacitance adversely affects the switching speed.

In addition to this difficulty, the device structure disclosed by Bulecea et al. causes different kinds of problems in making trench DMOS device with smaller cell size. The problems can be explained by referring to FIG. 1A for the patented device profile wherein the p-body regions 25 are formed to be deeper than the trench 40. The deep p-body regions 25 in the trench DMOS 70 disclosed by Bulecea et al. generate an undesirable side effect of creating the JFET regions between the deeper p-body thus causing the JFET resistance R-JFET to increase. Particularly for a high density device when the source regions are reduced to smaller dimension, a profile with the deeper p-body regions extend beneath the bottom of the trench would further reduce the width of the JFET regions thus causing further increase of the JFET resistance. Moreover, the threshold voltage of a device Vth is significantly increased due to a lateral diffusion of the p+ dopant to touch the channel regions.

In order to overcome this limitation, Ueno discloses in a US Pat. No. 5,086,007, entitled “Method of manufacturing an insulated Field Effect Transistor” (issued on Feb. 4, 1992), an improved insulated gate field effect transistor, e.g., a power MOSFET or an insulated gate bipolar transistor (IGBT). The structure of the Ueno's transistor which is formed in a semiconductor substrate with the drain, gate and source regions vertically disposed is shown in FIG. 1B as a cross sectional view. This vertical MOSFET device disclosed by Ueno includes a specially configured trench MOSFET transistor cell which is manufactured by a simplified method employing only a trench mask. In Ueno's process, a trench mask is employed to form the trenches first, which are then filled with polysilicon as gate material. An etch process is carried out to completely remove the polysilicon layer from the top surface of the substrate and a top portion in the trenches. The P-body implant and diffusion processes are performed to form the p-body followed by insulating the top portion of the trenches with an insulating material. A novel feature of this invention is to form the narrow source regions along the top edges of the trenches by a diffusion process. Narrow diffusion regions are formed by diffusion without requiring a source mask Source contacts are then formed over the top surface of the device.

With Ueno's simplified processes, the body and source regions are formed with self alignment after forming the gates in the trenches, the size of the transistor cells can be more conveniently reduced without being limited by the concerns of failure in satisfying a misalignment tolerance requirement. Ueno's invention further provides a simplified manufacture process such that the production cost can be reduced. A Ueno's device as shown in FIG. 1B however presents several technical difficulties. First of all, the difficulty of increased gate-to-drain capacitance is not resolved by Ueno's device. Similar to Bulucea et al., device-switching speed is affected when the interfacing areas between the trenched gates and the drain are increased.

Furthermore, Ueno's device produces a poor ohmic contact of the source region to the metal contact as a result of this manufacture process. As a diffusion process forms the source regions, the source doping concentration at the interface between the contact metal and the source regions is formed with a Gaussian distribution. The dopant concentration drops rapidly along a distance away from the trench edge. Due to a low doping concentration at the interface between the source region and the metal contact, the ohmic contact formed there has a poor performance characteristic. This poor ohmic contact also causes the sheet resistance of the p-body to increase. The ruggedness of the device is adversely affected due to a higher sheet resistance over the p-body since the parasitic NPN transistor becomes more susceptible to be incidentally turned on as the body resistance is increased which causes the voltage drop across the body region to increase. Therefore, even with a structure and processing method of manufacture to improve the transistor cell as described above, Ueno's device does not provide a complete and satisfactory solution to overcome the difficulties faced by the industry in an effort to further miniaturize the power DMOS transistors.

FIG. 1C is a cross sectional view of another prior art MOSFET power transistor where the P-body regions are formed with a depth shallower than the trenched gates. The difficulties of increased JFET resistance as that shown in FIG. 1A is circumvented. However, the gate-to-drain capacitance Cgd is also high due to large amount of interfacing areas between the gate and the drain around the lower portion of the trench. The device switching speed is adversely affected due to this greater gate-drain capacitance caused by greater amount of electrical charges retained in this greater gate-to-drain interface area.

Therefore, a need still exits in the art of power device fabrication, particularly for DMOS design and fabrication, to provide a structure and fabrication process that would resolve the difficulties caused by an increased gate-to-drain capacitance. More specifically, it is preferably that a transistor with a high cell density can be produced with reduced gate-to-drain interface areas thus reducing the gate-to-drain capacitance. Furthermore, it is desirable to provide a cell structure that improves the gate-oxide integrity at the bottom corners of the trenches. The trench bottom corners are often subjected to strong electrical stresses. It often lead to layer degradation and current leakage. By reducing the gate-to-drain interface areas and by protecting the bottom trench corners, the difficulties and limitations as discussed above can then be resolved.

### SUMMARY OF THE PRESENT INVENTION

It is therefore an object of the present invention to provide an improved trench DMOS structure, and fabrication process to overcome the aforementioned difficulties encountered in the prior art.

Specifically, it is an object of the present invention to provide an improved trench DMOS structure and fabrication process wherein the high density DMOS device is manufactured with transistor cells having a reduced gate-to-drain interfacing areas. This is achieved by forming body regions slightly below the trench gates and then laterally diffused to cover a small portion around the trench-bottom corners. With this body region wrapping-around gate-bottom-corner, the gate-to-drain interfacing areas are reduced. The difficulty of slower switching speed caused by large gate-to-drain interfacing areas in the DMOS device as that incurred in the prior art can be prevented.

Another object of this invention is provided an improved trench DMOS device having a reduced gate-to-drain interfacing area. This is achieved by forming body regions slightly below the trench gates and then laterally diffused to cover a small portion around the trench-bottom corners. The gate-to-drain interfacing areas are reduced and also the electrical stresses around the trench bottom corners are also reduced. The difficulty of gate-oxide degradation due to high intensity electric fields around bottom corners is therefore resolved.

Another object of this invention is provided an improved trench DMOS device having a reduced gate-to-drain interfacing area. This is achieved by forming body regions slightly below the trench gates and then laterally diffused to cover a small portion around the trench-bottom corners. The gate-to-drain interfacing areas are reduced. By carefully controlling the depth of the body regions to be almost the same as the depth of the trenched gates and carefully controlling the distance of lateral diffusion covering the bottom trench corners, no adverse effects of JFET resistance are generated.

Briefly, in a preferred embodiment, the present invention discloses a vertical DMOS transistor cell formed in a semiconductor substrate of a first conductivity type with a top surface and a bottom surface. The vertical DMOS transistor cell includes a trenched gate comprising polysilicon filling a trench opened from the top surface disposed substantially in a middle portion of the cell. The DMOS transistor cell further includes a source region of the first conductivity type surrounding the trenched gate near the top surface of the substrate. The DMOS transistor cell further includes a body region of a second conductivity type encompassing the source region. The body region extends vertically toward the bottom surface of the substrate having a depth slightly lower than a bottom of the trenched gate. The body region surrounding the trenched gate and further laterally extends with a small distance under the bottom of the trenched gate to cover all areas adjacent to bottom corners of the trenched gate.

The present invention further discloses a method for fabricating a DMOS transistor on a substrate, which has a reduced gate-to-drain capacitance and improved gate-oxide integrity. The method includes the steps of: (a) forming an epi-layer of a first conductivity type as a drain region on the substrate; (b) applying a trench mask for etching a trench followed by removing the mask and depositing a gate filling material then removed the gate filling material from above the top surface of the substrate thus forming a trenched gate; (c) performing a blank body implant with impurities of a second conductivity type followed by a body-diffusion process at an elevated temperature thus forming a body region surrounding the trenched gate wherein the body region extends vetrical to a depth slightly deeper than a bottom of the trenched gate and laterally diffused a small distance underneath the bottom of the trenched gate thus covering areas in the substrate surrounding trench bottom corners; (d) applying a source mask for performing source implant for forming a plurality of source regions followed by removing the source mask; (e) depositing an insulation layer on top of the power device followed by applying a contact mask for opening a plurality of source and gate contact openings followed by removing the contact mask; and (f) depositing a metal layer and applying a metal mask for etching and defining the gate metal and source metal segments. In a preferred embodiment, the step (e) of opening a plurality of source and gate contact openings further includes a step (g1) of performing a central high concentration body dopant implant through the source and gate openings to form a central high concentration body dopant region extending vertical and laterally below the source region for reducing a body resistance acorss the body region before removing the contact mask.

These and other objects and advantages of the present invention will no doubt become obvious to those of ordinary skill in the art after having read the following detailed description of the preferred embodiment which is illustrated in the various drawing figures.

### BRIEF DESCRIPTION OF THE DRAWINGS

FIG. 1A is a cross-sectional view of trench DMOS cell of a prior art including a deep p-body below the trenches in order to suppress breakdown in the gate oxide near the bottom corner of the trenches;

FIG. 1B is a cross-sectional view of another trench DMOS cell of a prior art including source regions formed by diffusion on the top portion of trench edges;

FIG. 1C is a cross sectional view of another trench DMOS cell of a prior art with shallow body region for eliminating the JFET resistance;

FIG. 2 is a cross sectional view of a preferred embodiment of this invention with body region extends vertically and laterally covering trench bottom corners to reduce the gate-drain capacitance and provide improved gate-oxide integrity; and

FIGS. 3A to 4F are a series of cross sectional views for showing the manufacture process of a novel trench DMOS transistor including a novel body region configuration for switching speed and gate-oxide integrity improvements.

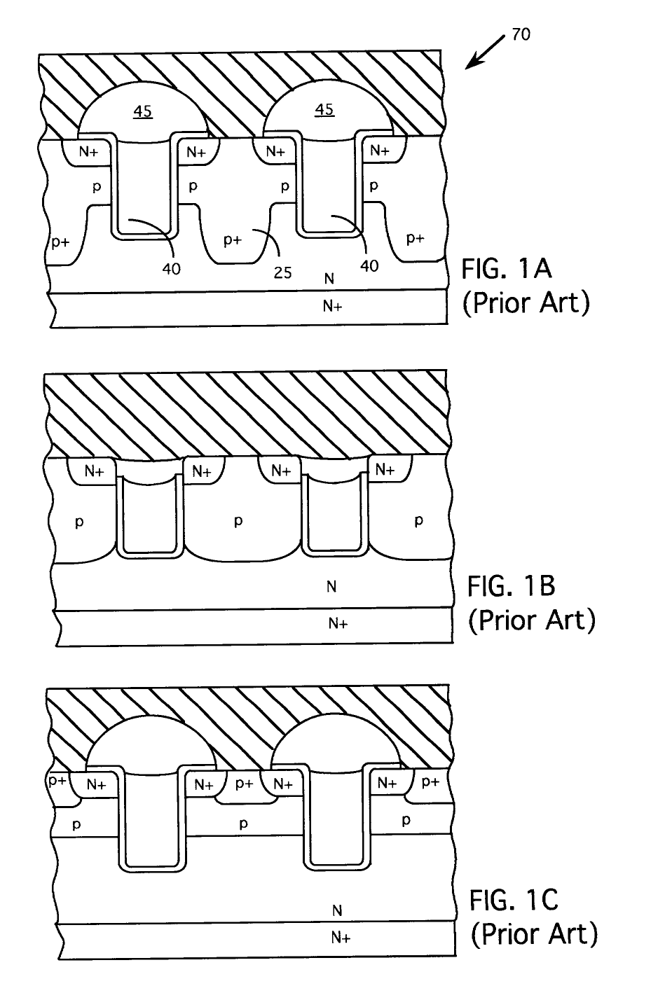

### DETAILED DESCRIPTION OF THE PREFERRED EMBODIMENT

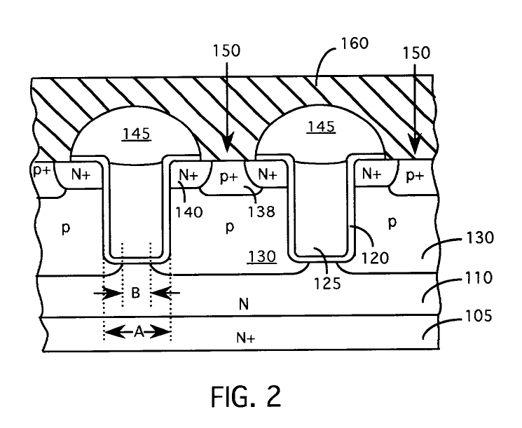

FIG. 2 shows a cross sectional view of a trenched DMOS transistor 100 of the present invention. The trenched DMOS transistor 100 is formed on a N+ substrate 105 supporting a N epi-layer 110 thereon. The N epitaxial layer 110 supports the DMOS transistor cell 100 with the bottom substrate layer functions as a drain for the transistor. The DMOS transistor cell 100 includes a trenched gate 125 disposed substantially in a middle portion of the cell. The trenched gate 125 is formed by filling a trench opened from the top surface of the substrate with polysilicon or other gate-filling materials. The trenched gate 125 is surrounded by a N⁺ source region 140 formed next to the trenched gate 125 near the top surface of the substrate. A P-body region 130 encompasses the source region 140 surrounding the trenched gate 125. The P-body region 130 extends vertically to a depth slightly deeper than the trenched gate 125. The P-body region 130 further extends laterally inwardly and underneath the trenched gate 125 to cover a small portion of the gate-interface area near the bottom trench corners of the trenched gate 125. The transistor cell 100 further includes a central high-concentration body-dopant region, i.e., a P⁺region 138 formed in the P-body region under the source region 140. This central high-concentration body-dopant region is formed for the purpose of reducing the parasitic resistance. By providing a higher body-dopant concentration than the surrounding P-body, the parasitic resistance over the body region 130 is lowered and the ruggedness of the transistor cell is improved. This is achieved by decreasing the voltage drop across the body regions by reducing the parasitic resistance thus decreasing the likelihood of incidentally turning on the parasitic NPN transistors. Above the top surface of the supporting substrate, an insulation layer 145 is formed to protect and insulate the DMOS transistor with a plurality of source contact openings 150 to form an electric contact between the source regions 140 and the source metal layer 160.

The trenched DMOS transistor 100 as shown has the advantage that the interface area between the trenched gate 125 and the drain 115 is decreased. This is achieved because the body region 130 now covers a portion of the areas under the bottom of the trenched gate 125. The gate-drain capacitance Cgd that is proportional to the interface area is therefore reduced. The transistor cell 100 as shown has another advantage that the gate-oxide integrity is improved. Traditionally, the gate-oxide layer 120 near the trench bottom corners is more vulnerable because of the higher electrical field intensity near the corners. Since the wrapped-around P-body region 130 now covers these corners, the integrity of the gate-oxide layer 120 near the bottom trench corners is improved.

According to FIG. 2 and above descriptions, this invention discloses a vertical DMOS power transistor 100 formed in a semiconductor substrate 105 with a top surface and a bottom surface. The vertical DMOS transistor cell 100 includes a trenched gate 125 comprising polysilicon filling a trench opened from the top surface disposed substantially in a middle portion of the cell. The DMOS transistor cell 100 further includes a source region 140 of the first conductivity type surrounding the trenched gate 125 near the top surface of the substrate. The DMOS transistor cell further includes a body region 130 of a second conductivity type surrounding the trenched gate 125 encompassing the source region 140. The body region 130 extends vertically toward the bottom surface of the substrate 105 having a depth slightly deeper than a bottom of the trenched gate 125. The body region 130 further extends laterally with a small distance under the bottom of the trenched gate 125 thus covering areas adjacent to bottom corners of the trenched gate 125 in the substrate defining a wrapping-around-bottom-corner body region 130.

In summary, the present invention discloses a semiconductor power device 100 formed in a semiconductor substrate 105 with a top surface and a bottom surface. The power device comprising a drain 105 disposed at the bottom surface, a trenched gate comprising a trench opened from the top surface of the substrate filled with a gate material filled therein. The power device further includes a source 140 near the top surface of the substrate surrounding the trenched gate 125. The power device further includes a body region 130 in the substrate surrounding the trenched gate 125 and forming a bottom-corner wrapping-around body region 130 wrapping around bottom trench corners of the trenched gate 125. In a preferred embodiment, the wrapping around body region 130 has a depth slightly deeper than a bottom of the trenched gate 125. And the wrapping around body region 130 laterally extends inwardly with a small distance less than one micrometer for covering the bottom trench corners of the trenched gate 125 thus constituting a wrapping-around-bottom-corner body region 130.

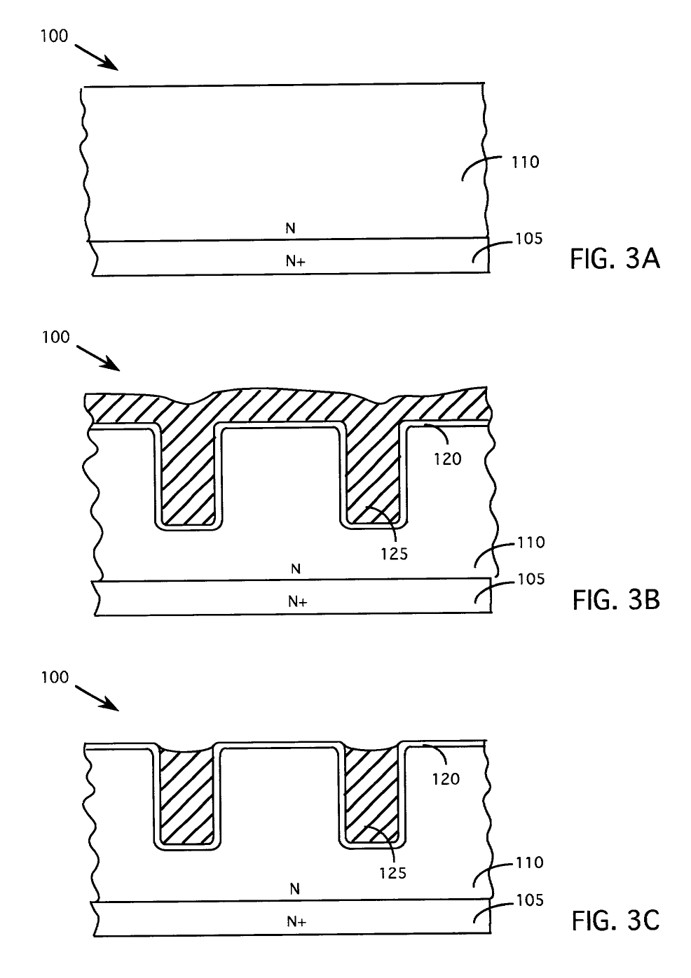

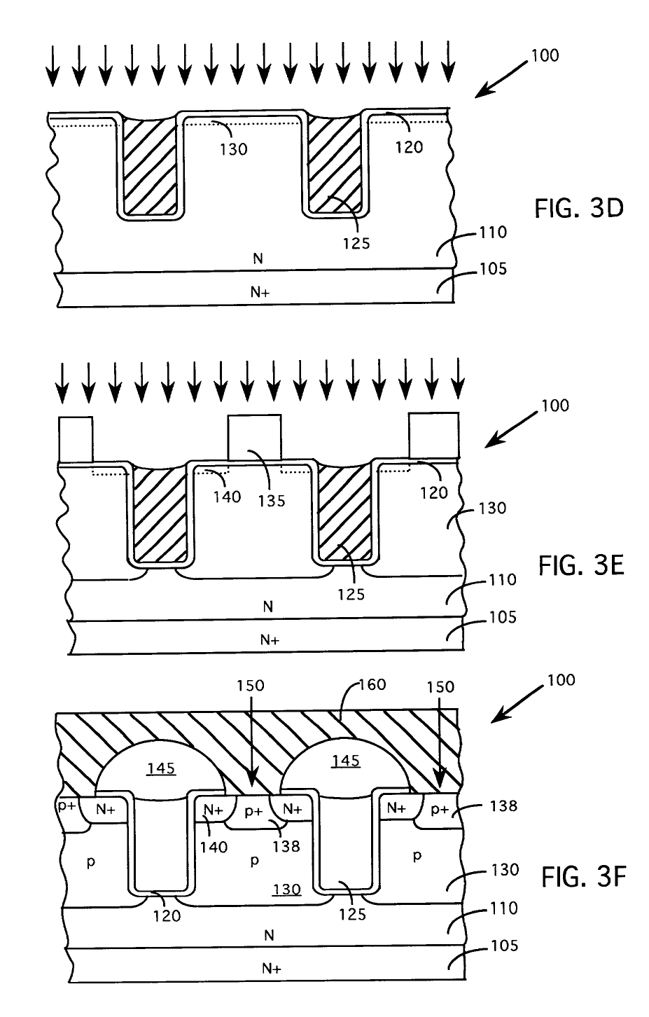

Please refer to FIGS. 3A to 3F for the processing steps carried out to manufacture a power DMOS device 100 of this invention. As shown in FIG. 3A, the processing steps begins by first growing a N epitaxial layer 110 with a resistivity ranging from 0.1 to 1.0 ohm-cm on top of a N+ substrate 105. The substrate has a resistivity of 0.001 to 0.007 ohm-cm. The thickness and the resistivity of the epitaxial layer 110 depend on the device requirements for the on-resistance and breakdown voltage. In a preferred embodiment, the thickness of the epi-layer 110 is about three to twenty microns (3-20 mm). Referring to FIG. 3B, a photoresist employed as a trench mask (not shown) to carry out a trench etch process. The trench etch process is a dry anisotropic etch process. Gate trenches of 1.0 to 2.0 microns in width and 1.0 to 2.0 micrometers in depth are formed. A sacrification oxidation process is applied which can be either a dry or wet oxidation process conducted at a temperature of 900-1100° C. to form oxide layer of approximately 300-2000 Å in thickness which is followed by a scarification oxide etch process. A gate oxidation process, which can be a wet or dry oxidation process are carried out to form a gate oxide layer 122 at a temperature of 800 to 1100° C. to form a layer of thickness in the range of 200 to 1,000 Å. A polysilicon deposition process is performed to deposit a polysilicon layer 125 ranging from 1.5 to 3.0 m in thickness. In FIG. 3C, a total etch process is performed to remove the polysilicon layer 125 and leaving only the gate material, e.g., the polysilicon in the bottom part of the trenches. A POCL₃ doping process is carried out at 950° C. to make the polysilicon layer 125 have a sheet resistance of 20-40 ohm/cm².

In FIG. 3D, a blank p-boy implant is carried out with boron ions at 30-100 Kev with an ion beam of 2×10¹⁵ to 1×10¹⁶/cm2 flux density to form the p-body region 130. A p-body diffusion process is then carried out at an elevated temperature of 1,000-1,200° C. for ten minutes to three hours to increase the depth of the p-body region 120 to 1.0-2.0 m. The body region 130 extends vertically to a depth slightly deeper than a bottom of the trenched gate 125 and laterally diffused a small distance underneath the bottom of the trenched gate 125 thus covering areas in the substrate surrounding trench bottom corners. Referring to FIG. 3E, a N⁺ block source mask 135 is applied to carry out an N⁺implant to form the N⁺region 140. The N⁺implantation is carried out with an arsenic or phosphorus ion beam 124 at an energy of 40-100 Kev and ion flux density of 5×10¹⁵ to 1×10¹⁶/cm² to form a plurality of N+ source region s 140.

Referring to FIG. 3F, the resist, i.e., the N+ blocking mask 135, is stripped and the N+ source regions 140 are driven into desired junction depth ranging from 0.2 to 1.0 m by a diffusion process at a temperature of 900-1000° C. for 10 minutes to two hours. An insulation layer 145, e.g., a BPSG or a PSG layer of approximately 5000-15,000 Å in thickness is deposited over the entire surface. A BPSG flow or BSG densification process is performed at 900-950° C. for thirty minutes to one hour. A contact mask (not shown) is employed to etch through the BPSG or the BSG insulation layer 145 to open a plurality of source contact openings in the core cell area and gate contact in the gate contact area (not shown). A central body dopant implant is performed by implanting through the contact openings with boron ions at 100-200 Kev with an ion beam of 5×10¹⁴ to 5×10¹⁵/cm² flux density thus forming a plurality of central high-concentration-body dopant regions 138 underneath the source regions 140. These central high-concentration body-dopant regions 138 are useful to reduce the parasitic resistance and thus increasing the device ruggedness. A layer of contact metal is deposited over the entire top surface. A metal mask (not shown) is then employed to etch and define the source contacts 150 and the gate contact 180.

Because the body region 130 now extends slightly deeper than the gate trench 125 and covering the bottom corners of the gate trenches, the total areas interfaced between the trenched gate 125 and the drain 110 are reduced. Furthermore, the wrapping around body region 130 now protects the bottom trench corners. The integrity of the gate-oxide layer 120 is improved particularly in the trench bottom corners.

According to FIGS. 3A to 3F and above description, the present invention further discloses a method for fabricating a DMOS power device on a substrate, which has high switching speed, enhanced ruggedness, reduced JFET resistance and improved gate-oxide integrity. The method includes the steps of: (a) forming an epi-layer 110 of a first conductivity type as a drain region on the substrate 105; (b) applying a trench mask for etching a trench followed by removing the mask and depositing a gate filling material then removed the gate filling material from above the top surface of the substrate thus forming a trenched gate 125; (c) performing a blank body implant with impurities of a second conductivity type followed by a body-diffusion process at an elevated temperature thus forming a body region 130 surrounding the trenched gate 125 wherein the body region extends vertically to a depth slightly deeper than a bottom of the trenched gate 125 and laterally diffused a small distance underneath the bottom of the trenched gate 125 thus covering areas in the substrate surrounding trench bottom corners; (d) applying a source mask 145 for performing source implant for forming a plurality of source regions 140 followed by removing the source mask; (e) depositing an insulation layer 145 on top of the power device followed by applying a contact mask for opening a plurality of source and gate contact openings 150 followed by removing the contact mask; and (f) depositing a metal layer and applying a metal mask for etching and defining the gate metal and source metal segments. In a preferred embodiment, the step (e) of opening a plurality of source and gate contact openings 150 further includes a step (g1) of performing a central high concentration body dopant implant through the source and gate openings to form a central high concentration body dopant region 138 extending vertical and laterally below the source region for reducing a body resistance across the body region 130 before removing the contact mask.

In summary, this invention also discloses a method for fabricating a trenched power transistor cell on a substrate 110. The method includes the steps of (a) forming a trenched gate 125 by opening a trench in the substrate 110 following by filling a gate-material therein; and (b) forming a body region 130 surrounding the trenched gate and extending vertically to a depth slightly deeper than a bottom of the trenched gate and laterally diffused a small distance underneath the bottom of the trenched gate thus covering areas adjacent to bottom corners of the trenched gate in the substrate defining a wrapping-around-bottom-corner body region 130.

Therefore, the present invention provides an improved trenched DMOS structure, and fabrication process to overcome the difficulties of a low switching speed, unreliable gate-oxide integrity and weakened device ruggedness for device of high cell density as encountered in the prior art. Specifically, the high density DMOS device is manufactured with transistor cells having reduced gate-to-drain interfacing areas. This is achieved by forming body regions slightly below the trench gates and then laterally diffused to cover a small portion around the trench-bottom corners. The gate-to-drain interfacing areas are reduced. The difficulty of slower switching speed caused by large gate-to-drain interfacing areas in the DMOS device as that incurred in the prior art can now be prevented. By forming body regions slightly below the trench gates and then laterally diffused to cover a small portion around the trench-bottom corners, gate-oxide integrity is improved. The electrical stresses around the trench bottom corners are reduced with the wrapped around body region. The difficulty of gate-oxide degradation due to high intensity electric fields around bottom corners is therefore resolved. By carefully controlling the depth of the body regions to be almost the same as the depth of the trenched gates and carefully controlling the distance of lateral diffusion covering the bottom trench corners, no adverse effects of JFET resistance are generated.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

We claim:

1. A vertical DMOS transistor cell formed in a semiconductor substrate of a first conductivity type with a top surface and a bottom surface, said DMOS transistor cell comprising:
a trenched gate comprising polysilicon filling a trench opened from said top surface disposed substantially in a middle portion of said transistor cell;
a source region of said first conductivity type surrounding said trenched gate near said top surface of said substrate;
a body region of a second conductivity type surrounding said trenched gate encompassing said source region and extending vertically toward said bottom surface of said substrate having a depth about 0.1 to 0.5 micrometers deeper than a bottom of said trenched gate, said body region further extending laterally with a distance about 0.1 to 0.5 micrometers under said bottom of said trenched gate thus covering areas adjacent to bottom corners of said trenched gate in said substrate defining a wrapping-around-bottom-corner body region; and
a central high-concentration body dopant region disposed in an upper portion of said body region surrounding said source region and extending vertically and laterally with a small portion thereunder having a higher body-dopant concentration than said body region.

2. A vertical DMOS transistor cell formed in a semiconductor substrate of a first conductivity type with a top surface and a bottom surface, said DMOS transistor cell comprising:
a trenched gate comprising polysilicon filling a trench opened from said top surface disposed substantially in a middle portion of said transistor cell;
a source region of said first conductivity type surrounding said trenched gate near said top surface of said substrate;
a body region of a second conductivity type surrounding said trenched gate encompassing said source region and extending vertically toward said bottom surface of said substrate having a depth slightly deeper than a bottom of said trenched gate, said body region further extending laterally with a small distance under said bottom of said trenched gate thus covering areas adjacent to bottom corners of said trenched gate in said substrate defining a wrappingaround-bottom-corner body region.

3. The vertical DMOS transistor cell of claim 2 wherein:
said body region has a depth about 0.1 to 0.5 micrometers deeper than a bottom of said trenched gate.

4. The vertical DMOS transistor cell of claim 2 wherein:
said body region extends laterally with a distance of about 0.1 to 0.5 micrometers under said bottom of said trenched gate.

5. The vertical DMOS transistor cell of claim 2 further comprising:
a central high-concentration body dopant region disposed in an upper portion of said body region surrounding said source region and extending vertically and laterally with a small portion thereunder having a higher body-dopant concentration than said body region.

6. A vertical power transistor cell formed in a semiconductor substrate of a first conductivity type with a top surface and a bottom surface, said power transistor cell comprising:
a trenched gate comprising a gate-material filling a trench opened from said top surface disposed substantially in a middle portion of said transistor cell;
a body region of a second conductivity type surrounding said trenched gate extending vertically toward said bottom surface of said substrate having a depth slightly deeper than a bottom of said trenched gate, said body region further extending laterally with a small distance under said bottom of said trenched gate thus covering areas adjacent to bottom corners of said trenched gate in said substrate defining a wrapping-around-bottom-corner body region.

7. The vertical power transistor cell of claim 6 wherein:
said body region has a depth about 0.1 to 0.5 micrometers deeper than a bottom of said trenched gate.

8. The vertical power transistor cell of claim 6 wherein:
said body region extends laterally with a distance of about 0.1 to 0.5 micrometers under said bottom of said trenched gate.

9. The vertical power transistor cell of claim 6 further comprising:
a source region of said first conductivity type encompassed in said body region surrounding said trenched gate near said top surface of said substrate; and
a central high-concentration body dopant region disposed in an upper portion of said body region surrounding said source region and extending vertically and laterally with a small portion thereunder having a higher body-dopant concentration than said body region.

10. A vertical power transistor cell formed in a semiconductor substrate of a first conductivity type with a top surface and a bottom surface, said power transistor cell comprising:
a trenched gate comprising a gate-material filling a trench opened from said top surface disposed substantially in a middle portion of said transistor cell;
a source region of said first conductivity type surrounding said trenched gate near said top surface of said substrate;
a body region of a second conductivity type surrounding said trenched gate encompassing said source region and extending vertically toward said bottom surface of said substrate having a depth slightly deeper than a bottom of said trenched gate, said body region further extending laterally with a small distance under said bottom of said trenched gate thus covering areas adjacent to bottom corners of said trenched gate in said substrate defining a wrapping-around-bottom-corner body region; and
a central high-concentration body dopant region disposed in an upper portion of said body region surrounding said source region and extending vertically and laterally with a small portion thereunder having a higher body-dopant concentration than said body region.

11. A method for fabricating a DMOS transistor on a substrate comprising:
(a) forming an epi-layer of a first conductivity type as a drain region on said substrate;
(b) applying a trench mask for etching a trench followed by removing said mask and depositing a gate filling material then removed said gate filling material from above said top surface of said substrate thus forming a trenched gate; and
(c) performing a blank body implant with impurities of a second conductivity type followed by a body-diffusion process at an elevated temperature thus forming a body region surrounding said trenched and extending vertically to a depth slightly deeper than a bottom of said trenched gate and laterally diffused a small distance underneath said bottom of said trenched gate thus covering areas adjacent to bottom corners of said trenched gate in said substrate defining a wrapping-around-bottom-corner body region.

12. The method for fabricating the DMOS transistor of claim 11 further comprising:
(d) applying a source mask for performing source implant for forming a plurality of source regions followed by removing said source mask;
(e) depositing an insulation layer on top of said power device followed by applying a contact mask for opening a plurality of source and gate contact openings followed by removing said contact mask; and
(f) depositing a metal layer and applying a metal mask for etching and defining said gate metal and source metal segments.

13. The method for fabricating said DMOS transistor of claim 12 wherein:
said step (f) of opening a plurality of source and gate contact openings further comprising a step (f1) of performing a central high concentration body dopant implant through said source and gate openings to form a central high concentration body dopant region extending vertical and laterally below said source region for reducing a body resistance across said body region before removing said contact mask.

14. The method for fabricating said DMOS transistor of claim 11 wherein:
said step of performing a body-diffusion process at an elevated temperature thus forming a body region surrounding said trenched body region is a step of diffusion said body region to have a depth about 0.1 to 0.5 micrometers deeper than a bottom of said trenched gate.

15. The method for fabricating said DMOS transistor of claim 11 wherein:
said step of performing a body-diffusion process at an elevated temperature thus forming a body region surrounding said trenched body region is a step of diffusion said body region to extend laterally with a distance of about 0.1 to 0.5 micrometers under said bottom of said trenched gate.

16. A method for fabricating a trenched power transistor cell on a substrate comprising:
(a) forming a trenched gate by opening a trench in said substrate following by filling a gate-material therein;
(b) forming a body region surrounding said trenched gate and extending vertically to a depth slightly deeper than a bottom of said trenched gate and laterally diffused a small distance underneath said bottom of said trenched gate thus covering areas adjacent to bottom corners of said trenched gate in said substrate defining a wrapping-around-bottom-corner body region.
